(19) United States
(12) Patent Application Publication
(10) Pub. No.: US 2017/0084509 A1
(43) Pub. Date: Mar. 23, 2017

(54) SUBSTRATE, CHIP PACKAGE WITH SAME AND METHOD FOR MANUFACTURING SAME

(71) Applicants: HongQiSheng Precision Electronics (QinHuangDao) Co.,Ltd., Qinhuangdao (CN); FuKui Precision Component (Shenzhen) Co., Ltd., Shenzhen (CN); Zhen Ding Technology Co., Ltd., Tayuan (TW)

(72) Inventor: YU-CHENG HUANG, New Taipei (TW)

(21) Appl. No.: 14/946,044

(22) Filed: Nov. 19, 2015

(30) Foreign Application Priority Data
Sep. 17, 2015 (CN) 201510590563.5

(51) Int. Cl. H01L 23/13; H05K 3/46; H05K 1/03; H05K 1/11; H01L 23/00; H01L 21/48

(52) U.S. Cl. CPC H01L 23/13; H01L 24/16; H01L 21/481; H05K 1/0326; H05K 1/032; H05K 1/115; H05K 3/46; H01L 2924/014; H01L 2924/15333; H05K 2201/0145; H05K 2201/0158

(57) ABSTRACT

A substrate includes a base layer, first and second circuit layers both coupled to the base layer, a third circuit layer, a fourth circuit layer and two solder resist layers. The first/second circuit layer defines a first/second opening. The third and fourth circuit layers are located at two sides of the first and second circuit layers. The solder resist layers cover outer faces of the third and fourth circuit layers. Each solder resist layer defines a window. The first opening is deviated from the second opening. The third and fourth circuit layers each have a portion exposed to the window to be a solder pad. The first circuit layer and the third circuit layer have a total thickness no more than that of the second circuit layer and the fourth circuit layer. A chip package with the substrate and a method for manufacturing the substrate are also provided.

### FIELD

The subject matter herein generally relates to circuit board technology, and particularly to a substrate, a chip package with the substrate and a method for manufacturing the substrate of the chip package.

### BACKGROUND

With increasing demand for intelligent electronic devices, in the field of packaging technology, thin type members for packaging products are needed for the electronic devices.

### BRIEF DESCRIPTION OF THE DRAWINGS

Implementations of the present technology will now be described, by way of example only, with reference to the attached figures.

FIG. 1 is a cross sectional view of a substrate in accordance with an embodiment of the present disclosure.

FIG. 2 is a cross sectional view of a chip package with the substrate in FIG. 1.

FIG. 3 is a flowchart of a method for manufacturing the substrate in FIG. 1.

FIG. 4 is a cross sectional view of a first copper clad laminate including a first copper foil and a second copper foil.

FIG. 5 is a cross sectional view of the first copper clad laminate in FIG. 4 with a first etchant resist film and a second etchant resist film.

FIG. 6 is a cross sectional view of the first copper clad laminate in FIG. 4 forming a first circuit layer by the first copper foil.

FIG. 7 is a cross sectional view of a second copper clad laminate laminated with the first copper clad laminate in FIG. 6, wherein the second copper clad laminate includes a third copper foil.

FIG. 8 shows the second copper foil in FIG. 7 being etched.

FIG. 9 is a cross sectional view of the structure in FIG. 8, with a third etchant resist film and a fourth etchant resist film.

FIG. 10 is a cross section view of the structure in FIG. 8, forming a second circuit layer by the second copper foil.

FIG. 11 is a cross section view of a third copper clad laminate laminated with the structure in FIG. 10.

FIG. 12 shows the structure in FIG. 11 defining a first through hole and a second through hole.

FIG. 13 shows the structure in FIG. 11 forming a first conductive hole and a second conductive hole.

FIG. 14 shows a fifth etchant resist film and a sixth etchant resist film formed on the third copper foil and the fourth copper foil in FIG. 13.

FIG. 15 shows a third circuit layer formed by the third copper foil and a fourth circuit layer formed by the fourth copper foil in FIG. 14.

FIG. 16 shows a seventh etchant resist film and an eighth etchant resist film formed on the third circuit layer and the fourth circuit layer in FIG. 15.

FIG. 17 shows the structure in FIG. 16 with a resistor layer exposed.

FIG. 18 shows an organic solder preservative formed on a solder pad of the substrate in FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The present disclosure is described in relation to a substrate of chip package. The substrate of chip package can include a base layer, a first circuit layer, a second circuit layer, a third circuit layer, a fourth circuit layer and two solder resist layers. The first circuit layer is coupled to a side of the base layer. The first circuit layer defines a first opening. The second circuit layer is coupled to another side of the base layer opposite to the first circuit layer. The second circuit layer defines a second opening. The third circuit layer is located at a side of the first circuit layer remote from the base layer and has an outer face. The fourth circuit layer is located at a side of the second circuit layer remote from the base layer and has an outer face. The two solder resist layers cover the outer face of the third circuit layer and the outer face of the fourth circuit layer. Each of the solder resist layers defines a window. The first opening of the first circuit layer is deviated from the second opening of the second circuit layer. Each of the third circuit layer and the fourth circuit layer has a portion thereof exposed to a corresponding window to be a solder pad. The first circuit layer and the third circuit layer have a total thickness no more than a total thickness of the second circuit layer and the fourth circuit layer.

The present disclosure is described in relation to a chip package. The chip package can include a substrate and a chip coupled to the substrate. The substrate can include a base layer, a first circuit layer, a second circuit layer, a third circuit layer, a fourth circuit layer and two solder resist layers. The first circuit layer is coupled to a side of the base layer. The first circuit layer defines a first opening. The second circuit layer is coupled to another side of the base layer opposite to the first circuit layer. The second circuit layer defines a second opening. The third circuit layer is located at a side of the first circuit layer remote from the base layer. The fourth circuit layer is located at a side of the second circuit layer remote from the base layer. The two solder resist layers cover outer faces of the third circuit layer and the fourth circuit layer. Each of the solder resist layers defines a window. The first opening of the first circuit layer is deviated from the second opening of the second circuit layer. Each of the third circuit layer and the fourth circuit layer has a portion thereof exposed to a corresponding window to be a solder pad. A total thickness of the first circuit layer and the third circuit layer is no more than a total thickness of the second circuit layer and the fourth circuit layer. The chip is coupled to the solder pads of the substrate.

The present disclosure is described further in relation to a method for manufacturing a substrate of chip package. The method can include the following components. A first copper clad laminate is provided. The first copper clad laminate includes a base layer, a first copper foil and a second copper foil located at two opposite sides of the base layer, respectively. A first circuit layer is formed from the first copper foil. The first circuit layer defines a first opening. A third copper foil is provided at a side of the first circuit layer remote from the base layer. A second circuit layer is formed from the second copper foil. The second circuit layer defines a second opening. A fourth copper foil is provided at a side of the second circuit layer remote from the base layer. A third circuit layer is formed from the third copper foil. A fourth circuit layer is formed from the fourth copper foil. Two solder resistor layers are formed to cover outer faces of the third circuit layer and the fourth circuit layer remote from the base layer. Portions of the outer faces of the third circuit layer and the fourth circuit layer are exposed out of the two solder resistor layers to be solder pads. The first opening of the first circuit layer is deviated from the second opening of the second circuit layer. A total thickness of the first circuit layer and the third circuit layer is no more than a total thickness of the second circuit layer and the fourth circuit layer.

FIG. 1 illustrates a substrate 100 of chip package of an embodiment of the present disclosure. The substrate 100 can include a base layer 13, a first circuit layer 110, a second circuit layer 120, a first bonding layer 23, a resistor layer 22, a third circuit layer 130, a second bonding layer 32, a fourth circuit layer 140 and a solder resist layer 160.

Material of the base layer 13 can be one or more selected from polyethylester, polypropylene, polycarbonate or other insulating material. A thickness of the base layer 13 can be in a range from 8 to 15 micrometers.

The first circuit layer 110 and the second circuit layer 120 are located at two opposite sides of the base layer 13.

In at least one embodiment, a thickness of the first circuit layer 110 is different from a thickness of the second circuit layer 120.

The first circuit layer 110, the base layer 13 and the second circuit layer 120 collectively form a capacitance of the substrate 100.

The first circuit layer 110 can define a first opening 112. The second circuit layer 120 can define a second opening 122. The first opening 112 is deviated from the second opening 122.

The first bonding layer 23 is coupled to a face of the first circuit layer 110 remote from the base layer 13. The resistor layer 22 is coupled to a face of the first bonding layer 23 remote from the base layer 13. The first bonding layer 23 is located between the first circuit layer 110 and the resistor layer 22.

The third circuit layer 130 is coupled to a face of the resistor layer 22 remote from the base layer 13. The third circuit layer 130 is located at a side of the first circuit layer 110 remote from the base layer 13.

The second bonding layer 32 is coupled to a face of the second circuit layer 120 remote from the base layer 13. The fourth circuit layer 140 is coupled to a face of the second bonding layer 32 remote from the base layer 13. The fourth circuit layer 140 is located at side of the second circuit layer 140 remote from the base layer 13. The second bonding layer 32 is located between the second circuit layer 120 and the fourth circuit layer 140.

The substrate 100 further includes a first conductive hole 340 and a second conductively hole 350 spaced from the first conductive hole 340. The first conductive hole 340 extends through the third circuit layer 130, the resistor layer 22, the first bonding layer 23, the first opening 112 of the circuit layer 110, the base layer 13, the second circuit layer 120, the second bonding layer 32 and the fourth circuit layer 140. The second conductive hole 350 extends through the third circuit layer 130, the resistor layer 22, the first bonding layer 23, the first circuit layer 110, the base layer 13, the second opening 122 of the second circuit layer 120, the second bonding layer 32 and the fourth circuit layer 140. The first conductive hole 340 is electrically connecting the third circuit layer 130, the fourth circuit layer 140 and the second circuit layer 120. The second conductive hole 350 is electrically connecting the third circuit layer 130, the fourth circuit layer 140, and the first circuit layer 110.

In the illustrated embodiment, the substrate 100 can include two solder resist layers 160 respectively covering outer faces of the third circuit layer 21 and the fourth circuit layer 140 remote from the base layer 13.

The two solder resist layers 160 are further filled in the first conductive hole 340 and the second conductive hole 350. The two solder resist layers 160 are coupled to each other in the first conductive hole 340 and the second conductive hole 350. In at least one embodiment, the two solder resist layers 160 are an integral one. Each of the solder resist layer 160 defines a window 161 exposed to an environment out of the substrate 100. In at least one embodiment, each of the solder resist layer 160 defines two windows 161 exposed to the environment out of the substrate 100. The third circuit layer 130 has two portions thereof exposed to the environment out of the substrate 100 via the two windows 161. The fourth circuit layer 140 has two portions thereof exposed to the environment out of the substrate 100 via the two windows 161. The exposed portions of the third circuit layer 130 and the fourth circuit layer 140 each form a solder pad 150 of the substrate 100.

A total thickness of the first circuit layer 110 and the third circuit layer 130 is no more than a total thickness of the second circuit layer 120 and the fourth circuit layer 140.

In at least one embodiment, a total thickness of the first circuit layer 110, the resistor layer 22 and the third circuit layer 130 is equal to a total thickness of the second circuit layer 120 and the fourth circuit layer 140.

In at least one alternative embodiment, the resistor layer 22 can be omitted, a total thickness of the first circuit layer 110 and the third circuit layer 130 is equal to the total thickness of the second circuit layer 120 and the fourth circuit layer 140.

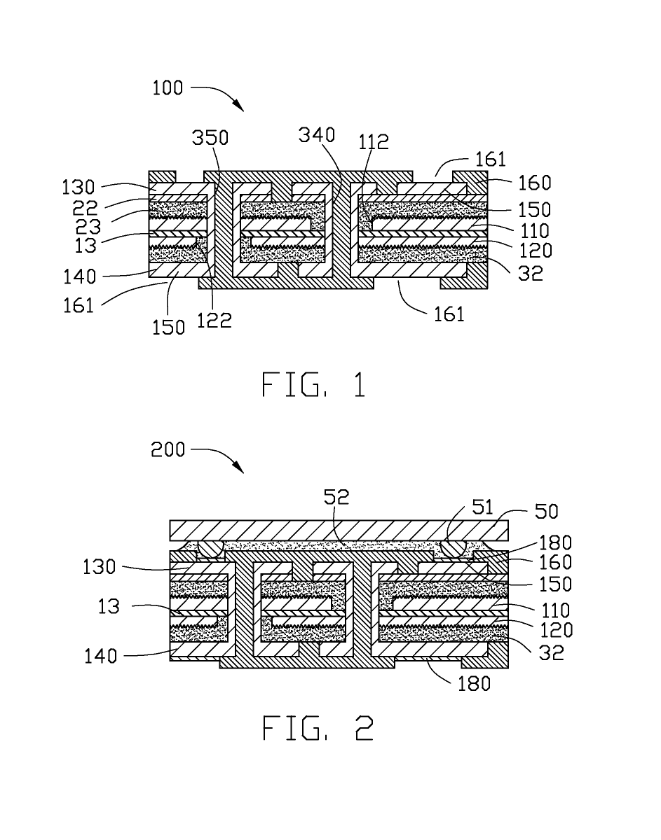

FIG. 2 illustrates that a chip package 200 can include the substrate 100 and a chip 50 coupled to the third circuit layer 130 of the substrate 100. The chip package 200 further includes two organic solder preservatives 180 coupled to the solder pads 150 of the substrate 100. The chip 50 is coupled to the organic solder preservatives 180 via two solder balls 51. In at least one embodiment, each organic solder preservative 180 is received in the corresponding window 161 and in directly physical contact with the corresponding solder pad 150 of the third circuit layer 130. The solder ball 51 is in directly physical contact with the corresponding organic solder preservative 180 and the chip 50. The chip package 200 can further includes an encapsulant 52 located between the organic solder preservative 180, the solder resist layer 160 and the chip 50.

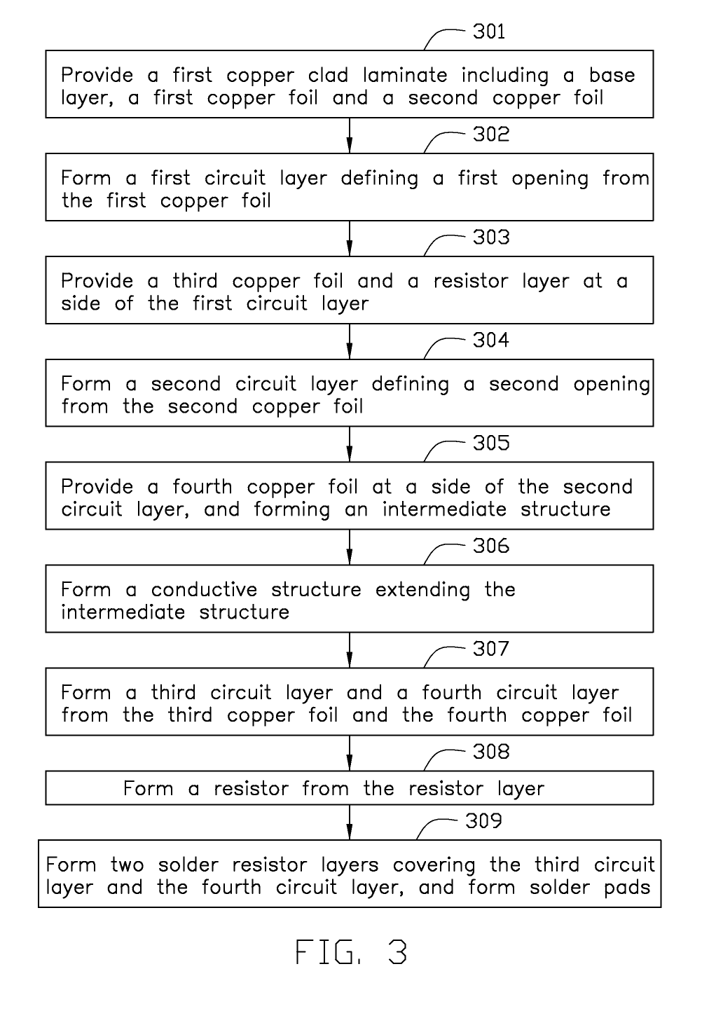

FIG. 3 illustrates a flowchart of an example method for manufacturing the substrate 100. The example method is provided by way of example, as there are a variety of ways to carry out the method. The example method described below can be carried out using the configurations illustrated in FIGS. 1 and 4-17, for example, and various elements of these figures are referenced in explaining the example method. Each block shown in FIG. 3 represents one or more processes, methods or subroutines, carried out in the example method. Furthermore, the illustrated order of blocks is illustrative only and the order of the blocks can change according to the present disclosure. Additional blocks can be added or fewer blocks may be utilized, without departing from this disclosure. The example method can begin at block 301.

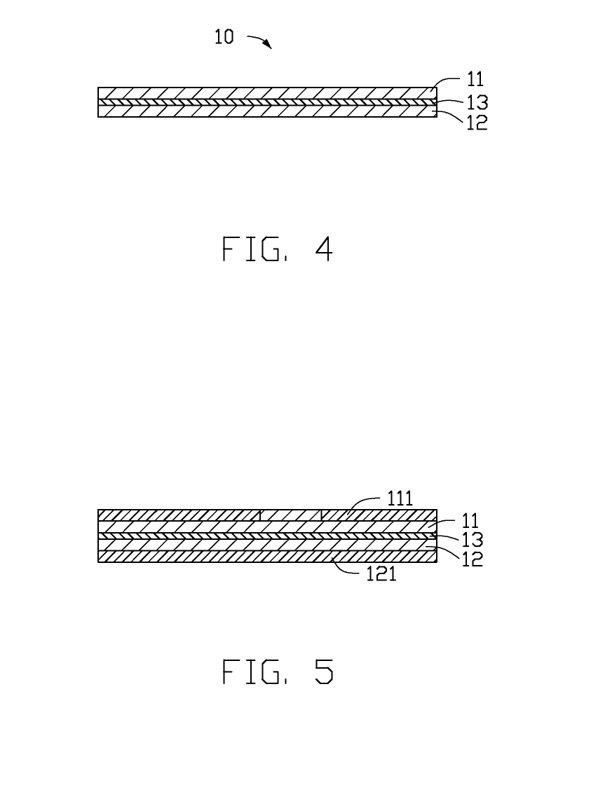

At block 301, also referring to FIG. 4, a first copper clad laminate 10 is provided. The first copper clad laminate 10 can be a two-sided flexible copper foil laminate (FCCL). The first copper clad laminate 10 includes a base layer 13, a first copper foil 11 and a second copper foil 12 located at two opposite sides of the base layer 13. The base layer 13 is located between the first copper foil 11 and the second copper foil 12. The base layer 13 is a support layer or a core layer of the substrate 100.

In at least one embodiment, the first copper foil 11 and the second copper foil 12 have the same thickness of 18 micrometers or 36 micrometers.

The base layer 13 is an insulating layer. Material of the base layer 13 can be one or more selected from polyethylester, polypropylene, polycarbonate or other insulating material. A thickness of the base layer 13 can be in a range from 8 to 15 micrometers. In the illustrated embodiment, the first copper foil 11 and the second copper foil 12 can act as two opposite electrodes of a film capacitor, the base layer 13 can act as a dielectric layer of the film capacitor of the substrate 100. In another word, the first copper foil 11, the second copper foil 12 and the base layer 13 collectively form the film capacitor of the substrate 100.

In the illustrated embodiment, when a voltage is applied to the first copper foil 11 and the second copper foil 12, a potential difference and an electric field are produced between the first copper foil 11 and the second copper foil 12. Electric charges are forced to move in the electric field and are blocked by the base layer 13, the electric charges are accumulated on the first copper foil 11 and the second copper foil 12, to thereby produce accumulation of the electric charges, the accumulation of the electric charges is called as capacitance.

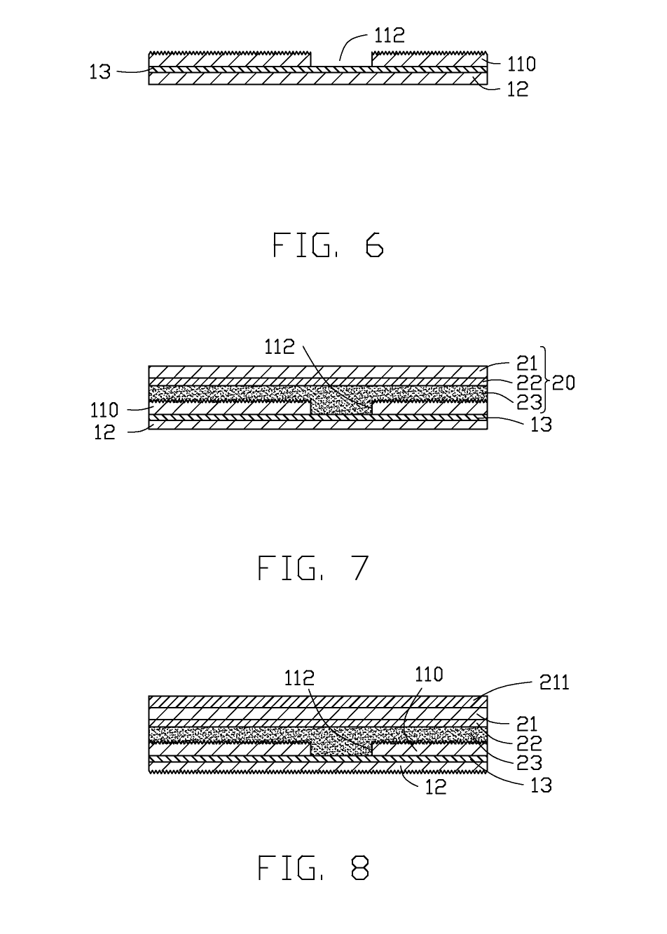

At block 302, also referring to FIG. 5 and FIG. 6, a first circuit layer 110 is formed by the first copper foil 11. The first circuit layer 110 defines a first opening 112. The base layer 13 is exposed to an environment out of the first copper clad laminate 10 via the first opening 112.

A method of forming the first circuit layer 110 can includes the followings.

A first etchant resist film 111 is formed or laminated to the first copper foil 11. A second etchant resist film 121 is formed or laminated to the second copper foil 12. The first etchant resist film 111 covers the first copper foil 11. The first etchant resist film 111 has a portion thereof exposed to ultraviolet lights. The ultraviolet lights make photoactive substance in the portion of the first etchant resist film 111 produce photochemical reaction, thereby finishing a process of image transfer. Another portion of the first etchant resist film 111 which is not exposed to the ultraviolet lights is removed by developing liquid. The developing liquid can be 1% NaCO3 solution. The first copper foil 11 has a portion thereof without covering of the first etchant resist film 111 is removed by etching solution, thereby forming the first opening 112. The etching solution can be copper chloride solution. The first etchant resist film 111 is striped from the first copper foil 11, thereby forming the first circuit layer 110 with the first opening 111. The second etchant resist film 121 is also striped from the second copper foil 12.

In at least one embodiment, before forming the first circuit layer 110, the first copper foil 11 can be reduced in thickness.

FIG. 6 illustrates that the first circuit layer 110 is further micro-etched to be roughened at a face thereof remote from the base layer 13.

At block 303, also referring to FIG. 7, a second copper clad laminate 20 is provided to laminate on the face of the first circuit layer 110 remote from the base layer 13. The first circuit layer 110 is located between the base layer 13 and the second copper clad laminate 20.

The second copper clad laminate 20 includes a third copper foil 21, a resistor layer 22 and a first bonding layer 23. The resistor layer 22 is located between the third cooper foil 21 and the first bonding layer 23. In at least one embodiment, the resistor layer 22 can be omitted, the second copper clad laminate 20 includes the third copper foil 21 and the first bonding layer 23.

The resistor layer 22 has a thickness in a range from 0.05 to 1 micrometer. The resistor layer 22 is a resistor 22 of the substrate 100. In at least one embodiment, the thickness of the resistor layer 22 can be adjusted be different thicknesses according to needed resistance value.

The first bonding layer 23 covers the face of the first circuit layer 110 and is filled in the first opening 112. In at least one embodiment, the first bonding layer 23 is in directly physical contact with the face of the first circuit layer 110 and the base layer 13 exposed in the first opening 112. The first bonding layer 23 can be a pre-impregnated (prepreg) material.

At block 304, also referring to FIGS. 8-10, a second copper foil 12 is reduced in thickness, and a second circuit layer 120 is formed by the reduced second cooper foil 12. The second circuit layer 120 defines a second opening 122. The second circuit layer 120 has a thickness less than that of the first circuit layer 110. In at least one alternative embodiment, the second circuit layer 120 has a thickness larger than that of the first circuit layer 110.

A method of forming the second circuit layer 120 can includes the followings.

Referring to FIG. 8, a third etchant resist film 211 is formed or laminated to a face of the third copper foil 21 remote from the first circuit layer 110. A face of the second copper foil 12 opposite to the base layer 13 is etched to reduce a thickness of the second copper foil 12. The second copper foil 12 is further micro-etched to form a roughened face remote from and opposite to the base layer 13, which enhances bonding force between the second copper foil 12 and other layer coupled to the second copper foil 12. In at least one embodiment, the whole face of the second copper foil 12 opposite to the base layer 13 is etched. In at least one embodiment, after etched, a difference between the thicknesses of the second copper foil 12 and the first circuit layer 110 is 5 micrometers.

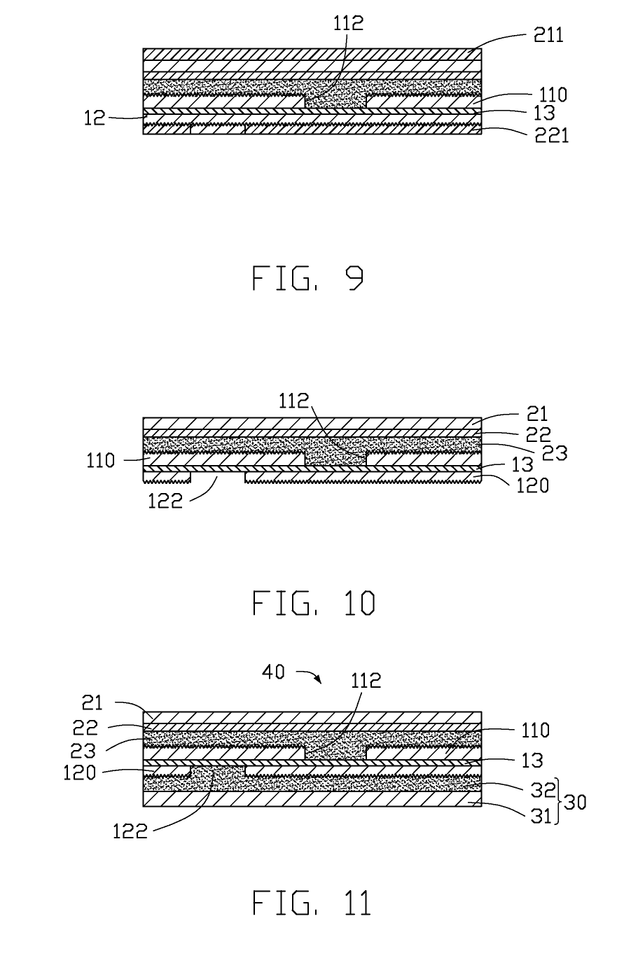

Referring to FIG. 9, a fourth etchant resist film 221 is formed or laminated to the face of the second copper foil 12 remote from the base layer 13. The fourth etchant resist film 221 covers the face of the second copper foil 12 remote from the base layer 13. The fourth etchant resist film 221 has a portion thereof exposed to ultraviolet lights. The ultraviolet lights make photoactive substance in the portion of the fourth etchant resist film 221 produce photochemical reaction, thereby finishing a process of image transfer. Another portion of the fourth etchant resist film 221 which is not exposed to the ultraviolet lights is removed by developing liquid. The developing liquid can be 1% NaCO3 solution. The second copper foil 12 has a portion thereof without covering of the fourth etchant resist film 221 is removed by etching solution, thereby forming the second opening 122. The etching solution can be copper chloride solution.

Referring to FIG. 10, the fourth etchant resist film 221 is striped from the second copper foil 12, thereby forming the second circuit layer 120 with the second opening 122. The third etchant resist film 121 is also striped from the third copper foil 21.

The base layer 13 is exposed to an environment out of the first copper clad laminate 10 via the second opening 122. The second opening 122 is deviated from the first opening 112 of the first circuit layer 110.

At block 305, also referring to FIG. 11, a third copper clad laminate 30 is provided to laminate on the face of the second circuit layer 120 remote from and opposite to the base layer 13. The first copper clad laminate 10, the second copper clad laminate 20 and the third copper clad laminated 30 are laminated together to form an intermediate structure 40 of the substrate 100.

The second circuit layer 120 is located between the base layer 13 and the third copper clad laminate 30.

The third copper clad laminate 30 includes a third copper foil 31 and a second bonding layer 32. In at least one embodiment, the third copper clad laminate 30 can further include a resistor layer located between the third copper foil 31 and the second bonding layer 32.

The second bonding layer 32 covers the face of the second circuit layer 120 remote from the base layer 13 and is filled in the second opening 122. In at least one embodiment, the second bonding layer 32 is in directly physical contact with the face of the second circuit layer 120 remote from the base layer 13 and the base layer 13 exposed in the second opening 122. The second bonding layer 32 can be a prepreg.

In at least one embodiment, the fourth copper foil 31 has a thickness different from the thickness of the third copper foil 21.

At block 306, also referring to FIGS. 12-13, a conductive structure 34 is formed in the intermediate structure 40 and to electrically connect the first circuit layer 110, the second circuit layer 120, the third copper foil 21 and the fourth copper foil 31. In the illustrated embodiment, the conductive structure 34 can include a first conducive hole 340 and a second conductive hole 350.

A method of forming the first conducive hole 340 and the second conductive hole 350 can include the followings.

Referring to FIG. 12, a first through hole 36 and a second through hole 37 are defined in the intermediate structure 40. The first through hole 36 corresponds to the first opening 112 and has a diameter less than that of the first opening 112 of the first circuit layer 110. The second through hole 37 corresponds to the second opening 122 and has a diameter less than that of the second opening 122 of the second circuit layer 120. The first through hole 36 and the second through hole 37 extend through the intermediate structure 40. The first through hole 36 extends the third copper foil 21, the resistor layer 22, the first bonding layer 23, the first opening 112, the base layer 13, the second circuit layer 120, the second bonding layer 32 and the fourth copper foil 31. The second through holes 37 extends the third copper foil 21, the resistor layer 22, the first bonding layer 23, the first circuit layer 110, the base layer 13, the second opening 122, the second bonding layer 32 and the fourth copper foil 31. The first through hole 36 and the second through hole 37 are formed by laser etching or mechanical drilling.

Referring to FIG. 13, inner walls of the first through hole 36 and the second through hole 37 are copper plating to from the first conductive hole 340 and the second conductive hole 350. The first conductive hole 340 is electrically connecting the third copper foil 21, the fourth copper foil 31 and the second circuit layer 120. The second conductive hole 350 is electrically connecting third copper foil 21, the fourth copper foil 31 and the first circuit layer 110. In at least one alternative embodiment, outer faces of the third copper foil 21 and the fourth copper foil 31 surrounding the first conductive hole 340 and the second conductive hole 350 are also copper plating to from copper pads (not shown) surrounding and integral with the first conductive hole 340 and the second conductive hole 350, here, each of the third copper foil 21 and the fourth copper foil 31 has a thickness at portions surrounding the first conductive hole 340 and the second conductive hole 350 lager than a thickness at the other portion thereof.

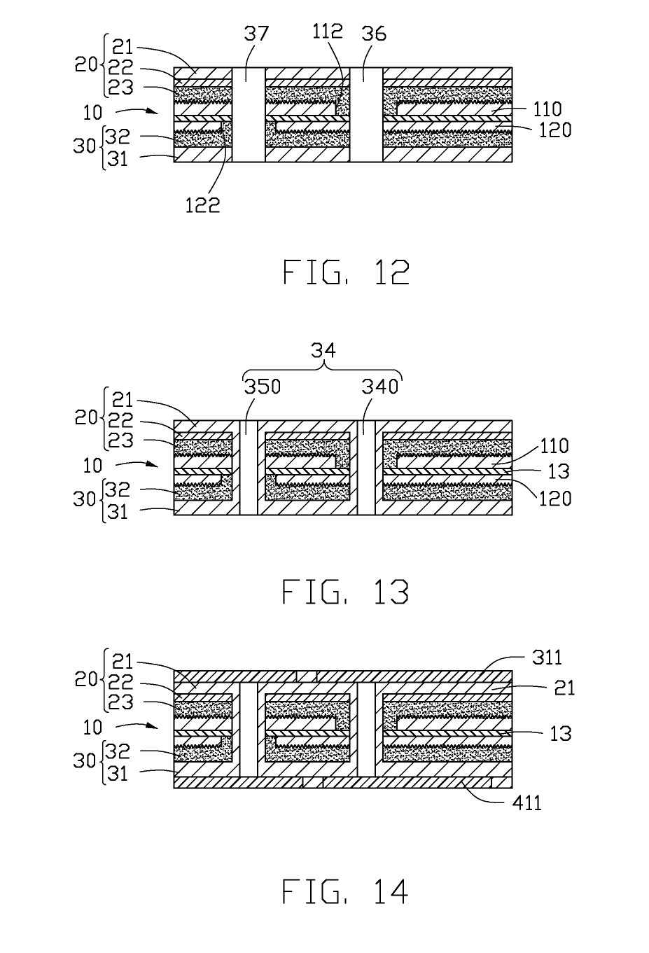

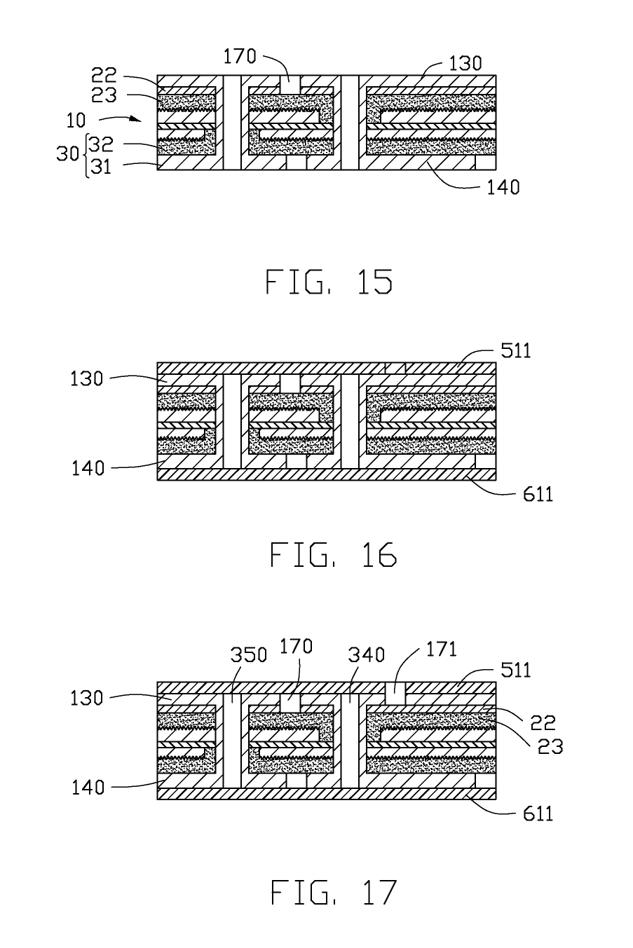

At block 307, also referring to FIG. 14 and FIG. 15, a third circuit layer 130 is formed from the third copper foil 21, and a fourth circuit layer 140 is formed from the fourth copper foil 31. A total thickness of the first circuit layer 110, the resistor layer 22 and the third circuit layer 130 is equal to a total thickness of the second circuit layer 120 and the fourth circuit layer 140. In at least one embodiment, when the resistor layer 22 is omitted, a total thickness of the first circuit layer 110 and the third circuit layer 130 is equal to the total thickness of the second circuit layer 120 and the fourth circuit layer 140, which can avoid warping of the substrate 100.

A method of forming the third circuit layer 130 and the fourth circuit layer 140 is similar to the method of forming the first circuit layer 110, and is simply illustrated as follows.

Referring to FIG. 14, a fifth etchant resist film 311 and a sixth etchant resist film 411 are formed or laminated to the outer faces of the third copper foil 21 and the fourth copper foil 31. The fifth etchant resist film 311 and the sixth etchant resist film 411 are processed by exposure and developing.

Referring to FIG. 15, the third copper foil 21 is etched to form the third circuit layer 130. The resistor layer 22 is also etched. A third opening 170 is defined by the etching process to the third copper foil 21 and the resistor layer 22. The third opening 170 extends through the third circuit layer 130 and the resistor layer 22. The first bonding layer 23 is exposed to an environment out of the intermediate structure 40 via the third opening 170. The fourth copper foil 31 is etched to form the fourth circuit layer 140. The fifth etchant resist film 311 and the sixth etchant resist film 411 are then striped.

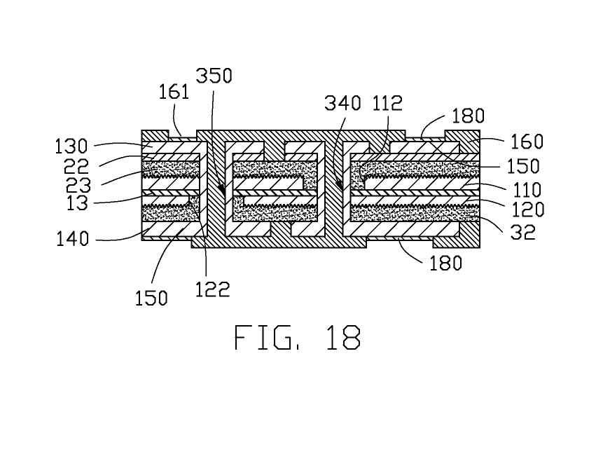

At block 308, also referring to FIG. 16 and FIG. 17, the third circuit layer 130 is processed to expose a portion of the resistor layer 22 to form a resistor of the substrate 100.

Referring to FIG. 16, a seventh etchant resist film 511 and an eighth etchant resist film 611 are respectively formed or laminated to outer faces of the third circuit layer 130 and the fourth circuit layer 140. A portion of the seventh etchant resist film 511 is processed by exposure and developing.

Referring to FIG. 17, the portion of the seventh etchant resist film 511 which is processed by exposure and developing and the third circuit layer 130 are etched to form a fourth opening 171 in the third circuit layer 130. The resistor layer 22 is exposed to an environment out of the intermediate structure 40 via the fourth opening 171. The seventh etchant resist film 511 and the eighth etchant resist film 611 are striped. Therefore, a resistor of the substrate 100 formed by the resistor layer 22 is obtained.

At block 309, also referring to FIG. 1, a plurality of solder pads 150 are formed by the third circuit layer 130 and the fourth circuit layer 140.

Two solder resist layers 160 are respectively formed on the third circuit layer 130 and the fourth circuit layer 140. The solder resist layers 160 are further filed in the first conductive hole 340, the second conductive hole 350, the third opening 170 and the fourth opening 171. The two solder resist layers 160 are coupled to each other in the first conductive hole 340 and the second conductive hole 350. In at least one embodiment, the two solder resist layers 160 are an integral one. Each of the solder resist layer 160 defines a window 161 exposed to an environment out of the substrate 100. In at least one embodiment, each of the solder resist layer 160 defines two windows 161 exposed to the environment out of the substrate 100. The third circuit layer 130 has two portions thereof exposed to the environment out of the substrate 100 via the two windows 161. The fourth circuit layer 140 has two portions thereof exposed to the environment out of the substrate 100 via the two windows 161. The exposed portions of the third circuit layer 130 and the fourth circuit layer 140 each form a solder pad of the substrate 100.

Referring to FIG. 18, two organic solder preservatives 180 are formed on the solder pads 150 of the substrate 100. Each organic solder preservative 180 is received in the corresponding window 161 and in directly physical contact with the corresponding solder pad 150 of the third circuit layer 130. The solder ball 51 is in directly physical contact with the corresponding organic solder preservative 180 and the chip 50. The chip package 200 can further includes an encapsulant 52 located between the organic solder preservative 180, the solder resist layer 160 and the chip 50.

The organic solder preservatives 180 can be replaced by scaling powder electroplated to the solder pads. The scaling powder can be one selected from nickel plating layer, gold plating layer, electroless Ni/Au, immersion silver or immersion tin.

Before forming the organic solder preservatives 180, the solder pads 150 is surface cleaning and surface treating.

Referring to FIG. 2, a chip 50 can be coupled to the organic solder preservatives 180 on the third circuit layer 130 of the substrate 100 via two solder balls 51. An encapsulant 52 can be filled between the organic solder preservative 180, the solder resist layer 160 and the chip 50. Therefore, a chip package 200 with the substrate 100 is obtained.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

1. A substrate of chip package comprising:
a base layer;
a first circuit layer coupled to a side of the base layer and defining a first opening;
a second circuit layer coupled to another side of the base layer opposite to the first circuit layer and defining a second opening;
a third circuit layer located at a side of the first circuit layer remote from the base layer and having an outer face;
a fourth circuit layer located at a side of the second circuit layer remote from the base layer and having an outer face; and
two solder resist layers covering the outer face of the third circuit layer and the outer face of the fourth circuit layer, each of the two solder resist layers defining a window;
wherein the first opening of the first circuit layer is deviated from the second opening of the second circuit layer, each of the third circuit layer and the fourth circuit layer has a portion thereof exposed to a corresponding window to be a solder pad, and the first circuit layer and the third circuit layer have a total thickness that is no more than a total thickness of the second circuit layer and the fourth circuit layer.

2. The substrate of claim 1, wherein the first circuit layer has a thickness different from that of the second circuit layer.

3. The substrate of claim 2, wherein the total thickness of the first circuit layer and the third circuit layer is equal to the total thickness of the second circuit layer and the fourth circuit layer.

4. The substrate of claim 2, further comprising a resistor layer located between the first circuit layer and the third circuit layer.

5. The substrate of claim 4, wherein a total thickness of the first circuit layer, the resistor layer and the third circuit layer is equal to the total thickness of the second circuit layer and the fourth circuit layer.

6. The substrate of claim 5, further comprising a first conductive hole electrically connecting the third circuit layer, the fourth circuit layer and the second circuit layer, and a second conductive hole electrically connecting the third circuit layer, the fourth circuit layer and the first circuit layer.

7. The substrate of claim 5, wherein the first conductive hole extends through the third circuit layer, the resistor layer, the first opening, the base layer, the second circuit layer and the fourth circuit layer, the second conductive hole extending through the third circuit layer, the resistor layer, the first circuit layer, the base layer, the second opening and the fourth circuit layer.

8. The substrate of claim 1, wherein material of the base layer is one or more selected from polyethylester, polypropylene, polycarbonate or other insulating material.

9. A chip package comprising:
a substrate comprising:
a base layer;
a first circuit layer coupled to a side of the base layer, and defining a first opening;
a second circuit layer coupled to another side of the base layer opposite to the first circuit layer, and defining a second opening;
a third circuit layer located at a side of the first circuit layer remote from the base layer;
a fourth circuit layer located at a side of the second circuit layer remote from the base layer; and
two solder resist layers covering outer faces of the third circuit layer and the fourth circuit layer, each of the solder resist layers defining a window;
wherein the first opening of the first circuit layer is deviated from the second opening of the second circuit layer, each of the third circuit layer and the fourth circuit layer has a portion thereof exposed to a corresponding window to be a solder pad, a total thickness of the first circuit layer and the third circuit layer is no more than a total thickness of the second circuit layer and the fourth circuit layer; and
a chip coupled to the solder pads of the substrate.

10. The chip package of claim 9, wherein the first circuit layer has a thickness different from that of the second circuit layer.

11. The chip package of claim 10, further comprising a resistor layer located between the first circuit layer and the third circuit layer.

12. The chip package of claim 11, wherein a total thickness of the first circuit layer, the resistor layer and the third circuit layer is equal to the total thickness of the second circuit layer and the fourth circuit layer.

13. The chip package of claim 12, further comprising a first conductive hole electrically connecting the third circuit layer, the fourth circuit layer and the second circuit layer, and a second conductive hole electrically connecting the third circuit layer, the fourth circuit layer and the first circuit layer.

14. The chip package of claim 13, wherein the first conductive hole extends through the third circuit layer, the resistor layer, the first opening, the base layer, the second circuit layer and the fourth circuit layer, the second conductive hole extending through the third circuit layer, the resistor layer, the first circuit layer, the base layer, the second opening and the fourth circuit layer.

15. The chip package of claim 9, further comprising an organic solder preservative coupled to the solder pad, wherein the organic solder preservative is received in the window, the chip being coupled to the organic solder preservative.

16. The chip package of claim 15, wherein the chip is coupled to the organic solder preservative via a solder ball.

17. A method for manufacturing a substrate of chip package, comprising:
providing a first copper clad laminate comprising a base layer, a first copper foil and a second copper foil located at two opposite sides of the base layer, respectively;
forming a first circuit layer from the first copper foil, the first circuit layer defining a first opening;
providing a third copper foil at a side of the first circuit layer remote from the base layer;
forming a second circuit layer from the second copper foil, the second circuit layer defining a second opening;
providing a fourth copper foil at a side of the second circuit layer remote from the base layer;
forming a third circuit layer from the third copper foil, and forming a fourth circuit layer from the fourth copper foil; and
forming two solder resistor layers covering outer faces of the third circuit layer and the fourth circuit layer remote from the base layer, exposing portions of the outer faces of the third circuit layer and the fourth circuit layer out of the two solder resistor layers to be solder pads;
wherein the first opening of the first circuit layer is deviated from the second opening of the second circuit layer, a total thickness of the first circuit layer and the third circuit layer is no more than a total thickness of the second circuit layer and the fourth circuit layer.

18. The method of claim 17, wherein the first circuit layer has a thickness different from that of the second circuit layer.

19. The method of claim 18, before providing the third copper foil, further comprising:
forming a resistor layer at the side of the first circuit layer remote from the base layer, wherein the third copper foil is coupled to a side of the resistor layer remote from the base layer.

20. The method of claim 19, wherein a total thickness of the first circuit layer, the resistor layer and the third circuit layer is equal to the total thickness of the second circuit layer and the fourth circuit layer.
